(19) United States
(12) Patent Application Publication
(10) Pub. No.: US 2019/0181352 A1
(43) Pub. Date: Jun. 13, 2019

(54) METHOD FOR PREPARING ORGANIC FILM, ORGANIC LIGHT EMITTING DIODE, AND DISPLAY DEVICE

(71) Applicants: BOE TECHNOLOGY GROUP CO., LTD., Beijing (CN); CHONGQING BOE OPTOELECTRONICS TECHNOLOGY CO., LTD., Chongqing (CN)

(72) Inventors: Cunpeng ZHONG, Beijing (CN); Yanfeng LAI, Beijing (CN)

(21) Appl. No.: 16/168,911

(22) Filed: Oct. 24, 2018

(30) Foreign Application Priority Data
Dec. 12, 2017 (CN) 201711320924.X

(51) Int. Cl. H01L 51/00; H01L 51/56; H01L 51/50

(52) U.S. Cl. CPC H01L 51/0072; H01L 51/0074; H01L 51/0068; H01L 51/56; H01L 51/5072; H01L 51/5092; H01L 51/5096; H01L 51/0096; H01L 51/5056; H01L 51/5012

(57) ABSTRACT

A method for manufacturing an organic film for an organic light emitting diode, includes: dispersing an organic material solution in a matrix solution to form an organic material layer; transferring the organic material layer to a base substrate, so as to obtain an organic film in which molecules are arranged in order; wherein the organic material solution includes an organic material, and a molecular structure of the organic material includes a hydrophilic group and a hydrophobic group. An organic light emitting diode and a display device are also provided.

The present disclosure claims priority of Chinese Patent Application No. 201711320924.X filed on Dec. 12, 2017, the disclosure of which is hereby entirely incorporated by reference as a part of the present disclosure.

### TECHNICAL FIELD

Embodiments of the present disclosure relate to a method for preparing organic film, an organic light emitting diode, and a display device.

### BACKGROUND

Organic light emitting diodes have the advantages of being thin, transparent, surface emitting light, self-illuminating, flexible and bendable, and are widely used in various fields such as illumination and display. Organic light emitting diodes typically include an anode, a cathode, and an organic functional layer between the anode and the cathode, such as a light emitting layer. When an appropriate voltage is applied across the anode and the cathode of the organic light emitting diode, holes injected from the anode and electrons injected from the cathode are combined in the light emitting layer and are excited to generate light. At present, the organic functional layer of the organic light emitting diode is usually formed by vacuum evaporation, spin coating, inkjet printing or screen printing.

### SUMMARY

At least one embodiments of the present disclosure provides a method for manufacturing an organic film for an organic light emitting diode, comprising: dispersing an organic material solution in a matrix solution to form an organic material layer; and transferring the organic material layer to a base substrate, so as to obtain an organic film in which molecules are arranged in order; wherein the organic material solution comprises an organic material, and a molecular structure of the organic material comprises a hydrophilic group and a hydrophobic group.

In the method for manufacturing the organic film for the organic light emitting diode according to one embodiment of the present disclosure, the organic material layer is a mono-molecule layer in which molecules are arranged in order.

In the method for manufacturing the organic film for the organic light emitting diode according to one embodiment of the present disclosure, the organic material is an organic material for forming an electron transport layer, an electron injection layer, an electrode blocking layer, a hole transport layer, a hole injection layer, a hole blocking layer, or a light emitting layer.

In the method for manufacturing the organic film for the organic light emitting diode according to one embodiment of the present disclosure, the organic material is at least one of polyvinylcarbazole, poly 3,4-ethylenedioxythiophene-polystyrenesulfonic acid, perylenetetracarboxylic dianhydride, 8-hydroxyquinoline aluminum, tetrafluorotetracyanoquinodimethane, 7,7,8,8-tetracyanoquinodimethane, 4,4′,4″-tris(2-naphthylphenylamino)triphenylam Me, 4,4′-Bis(N-carbazole)-1-1′-biphenyl, 1,3-bis(triphenylsilyl)benzene, 4,4′-bis(9-carbazolyl)-2,2′-dimethylbiphenyl, Bis(10-hydroxybenzo[h]quinolinato)beryllium, 1,3, 5-tris(4-pyridin-3-ylphenyl)benzene, 8-hydroxyquinoline aluminum and Bis[2-(2-pyridinyl)phenolato]beryllium.

In the method for manufacturing the organic film for the organic light emitting diode according to one embodiment of the present disclosure, the organic material solution comprises a solvent, and the solvent is chloroform, toluene, xylene or tetrahydrofuran.

In the method for manufacturing the organic film for the organic light emitting diode according to one embodiment of the present disclosure, the organic material solution further comprises an additive that makes molecules of the organic material form a mono-molecule layer on a surface of the matrix solution.

In the method for manufacturing the organic film for the organic light emitting diode according to one embodiment of the present disclosure, the additive is at least one of octadecylamine, stearic acid, behenic acid or eicosanoid acid, and the additive is configured to be a catalyst.

In the method for manufacturing the organic film for the organic light emitting diode according to one embodiment of the present disclosure, the matrix solution is water or a hydrophilic solution.

In one embodiment of the present disclosure, the method for manufacturing the organic film for the organic light emitting diode comprises: immersing the base substrate in the matrix solution; dispersing the organic material solution on a surface of the matrix solution; and then pulling the base substrate out of the matrix solution so as to transfer the organic material layer onto the base substrate.

In one embodiment of the present disclosure, the method for manufacturing the organic film for the organic light emitting diode further comprises treating the base substrate so as to make the a surface of the base substrate hydrophilic or hydrophobic.

In one embodiment of the present disclosure, the method for manufacturing the organic film for the organic light emitting diode further comprises drying the organic material layer after transferring the organic material layer onto the base substrate.

In the method for manufacturing the organic film for the organic light emitting diode according to one embodiment of the present disclosure, the base substrate is a cathode material layer, an anode material layer, or an organic functional layer.

In the method for manufacturing the organic film for the organic light emitting diode according to one embodiment of the present disclosure, each process of the method is carried out in a vacuum environment.

At least one embodiment of the present disclosure provides a method for manufacturing an organic light emitting diode, comprising forming a cathode, an anode and an organic functional layer between the cathode and the anode, wherein the organic functional layer is formed through any of the methods for manufacturing the organic film for the organic light emitting diode as described above.

At least one embodiment of the present disclosure provides an organic light emitting diode, comprising a cathode, an anode, and an organic functional layer between the cathode and the anode, wherein the organic functional layer comprises at least one of the organic films as described above, molecules of the organic film arc arranged in order, and the molecules of the organic functional layer comprise a hydrophilic group and a hydrophobic group.

In the organic light emitting diode according to one embodiment of the present disclosure, the organic film is a mono-molecule layer in which molecules are arranged in order.

In the organic light emitting diode according to one embodiment of the present disclosure, the organic functional layer comprises at least one of an electron transport layer, an electron injection layer, an electron blocking layer, a hole transport layer, a hole injection layer, a hole blocking layer, and a light emitting layer.

In the organic light emitting diode according to one embodiment of the present disclosure, material for the organic functional layer comprises at least one of polyvinylcarbazole, poly 3,4-ethylenedioxythiophene-polystyrenesulfonic acid, perylenetetracarboxylic dianhydride, 8-hydroxyquinoline aluminum, tetrafluorotetracyanoquinodimethane, 7,7,8,8-tetracyanoquinodimethane, 4,4′,4″-tris(2-naphthylphenylamino)triphenylamine, 4,4′-Bis(N-carbazole)-1-1-biphenyl, 1,3-bis(triphenylsilyl)benzene, 4,4′-bis(9-carbazolyl)-2,2′-dimethylbiphenyl, Bis(10-hydroxybenzo[h]quinolinato)beryllium, 1,3,5-tris(4-pyridin-3-ylphenyl)benzene, 8-hydroxyquinoline aluminum and Bis[2-(2-pyridinyl)phenolato]beryllium.

At least one embodiment of the present disclosure provides an organic light emitting display device, comprising any of the organic light emitting diodes as described above.

Molecules of the organic film prepared by the methods according to the embodiments of the present disclosure are arranged in order, and when the organic film is used as an organic functional layer for an organic light emitting diode, both the electron transport efficiency and the hole transport efficiency are increased such that the electrical conductivity of the organic film can be improved, thereby improving the photoelectron transport efficiency of the organic light emitting diode.

### BRIEF DESCRIPTION OF THE DRAWINGS

In order to clearly illustrate the technical solutions of the embodiments of the disclosure, the drawings of the embodiments will be briefly described in the following; it is obvious that the drawings described below arc only related to some embodiments of the disclosure and thus are not limitative of the disclosure.

FIG. 1 is a flow chart of a method for preparing an organic thin film according to an embodiment of the present disclosure;

FIG. 2A-2D are schematic views showing a process of preparing an organic thin film according to an embodiment of the present disclosure;

FIG. 3 is a schematic view showing an organic thin film having a multilayer structure according to an embodiment of the present disclosure;

FIG. 4A is a schematic view showing a molecular structure of an organic film with a monomolecular layer according to an embodiment of the present disclosure;

FIG. 4B is a schematic view showing a molecular structure of an organic film with multiple molecular layers according to an embodiment of the present disclosure;

FIG. 5 is a schematic diagram of an organic light emitting diode according to an embodiment of the present disclosure; and

FIG. 6 is a schematic diagram of an organic light emitting display device according to an embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise defined, the technical terms or scientific terms used herein should have the same meaning as commonly understood by one of ordinary skill in the art. The terms “first”, “second” and similar words used in the present disclosure do not denote any order, quantity, or importance, but are merely intended to distinguish different components. Words like “including” or “comprising” and etc. mean that an element or an article before them contains an element/elements or an article/articles listed thereafter, while not excluding other elements or articles. Words such as “connect” or “couple” or the like are not to be limited to physical or mechanical connections, but may include electrical connections, either direct or indirect. Terms of “up”, “down”, “left”, “right” and etc. are merely intended to indicate relative positional relationships. If the absolute position of the described object is changed, the relative positional relationship will be changed accordingly.

As described above, the organic functional layer of the organic light emitting diode is usually formed by vacuum evaporation, spin coating, ink jet printing or screen printing. However, the inventors of the present disclosure have found in research that, in the organic functional layer, the carrier mobility is relevant to the strength of the chemical bond in molecular structure. The stronger the chemical bond in the molecular structure of the organic functional layer, the higher the carrier mobility, and the higher the matching ratio of electrons to holes. In an organic functional layer formed by vacuum evaporation, spin coating, inkjet printing or screen printing, the molecules are arranged disorderedly, and these disordered molecules are usually bonded through van der Waals forces therebetween, while The bond energy between Van der Waals forces is lower than 100 kJ/mol. Therefore, when electrons and holes are transported between organic molecules arranged disorderedly, emission quenching is likely to occur, resulting in low efficiency in matching of electron-hole pair, such that the luminous efficiency of organic LEDs is often not higher than 25%.

At least one embodiment of the present disclosure provides a method for preparing an organic thin film for an organic light emitting diode (OLED), comprising: dispersing an organic material solution in a matrix solution to form an organic material layer; transferring the organic material layer to a base substrate, so as to obtain an organic film in which molecules are arranged in order; wherein the organic material solution comprises an organic material, and a molecular structure of the organic material comprises a hydrophilic group and a hydrophobic group.

At least one embodiment of the present disclosure provides an organic light emitting diode comprising a cathode, an anode, and an organic functional layer between the cathode and the anode, wherein the organic functional layer comprises at least one organic film in which molecules are arranged in order, and a molecular structure of material for the organic functional layer comprises a hydrophilic group and a hydrophobic group.

At least one embodiment of the present disclosure provides an organic light emitting display device comprising the organic light emitting diode as described above.

Hereinafter, a method for preparing an organic thin film, an organic light emitting diode, and a display device of the present disclosure will be described by way of several embodiments.

An embodiment of the present disclosure provides a method for preparing an organic thin film for an organic light emitting diode (OLED), comprising: dispersing an organic material solution in a matrix solution so as to form an organic material layer; transferring the organic material layer to a base substrate, so as to obtain an organic film in which molecules are arranged in order; wherein the organic material solution comprises an organic material, and a molecular structure of the organic material comprises a hydrophilic group and a hydrophobic group.

For example, FIG. 1 is a flowchart of a method for preparing an organic thin film in an example of the embodiment, and the method comprises steps S101-S102.

Step S101: forming an organic material layer.

In the embodiment, for example, an organic material solution is dispersed in a matrix solution so as to form an organic material layer. For example, the organic material solution comprises an organic material, which can be, for example, an organic material for preparing an electron transport layer, an electron injection layer, an electron blocking layer, a hole transport layer, a hole injection layer, a hole blocking layer, or a light emitting layer. For example, the organic material solution further comprises a solvent, and the organic material can be dissolved in the solvent. Therefore, the type of the solvent can be selected according to the properties of the organic material and actual requirements, and the organic material solution having a certain concentration can be formulated, and the organic material solution is insoluble in the matrix solution. In some examples, the density of the organic material solution is less than the density of the matrix solution such that the organic material solution can spread over the matrix solution.

In this embodiment, the organic material comprises a hydrophilic group and a hydrophobic group in the molecular structure. The matrix solution can be, for example, water or a hydrophilic solution, such as a solution having a density close to that of water such as triglyceride, so that when the organic material solution is spread on the matrix solution, the hydrophilic group of the organic material molecule can be attracted to the matrix solution, and the hydrophobic group repels the matrix solution, so that molecules of the organic material can form an organic material layer arranged in order on the surface of the matrix solution, for example, forming a monomolecular layer in which molecules are arranged in order, the side of the monomolecular layer adjacent to the substrate solution is the hydrophilic group and the side of monomolecular layer away from the matrix solution is the hydrophobic group.

In this embodiment, the organic material can be, for example, polyvinylcarbazole, poly 3,4-ethylenedioxythiophene-polystyrenesulfonic acid, perylenetetracarboxylic dianhydride, 8-hydroxyquinoline aluminum, tetrafluorotetracyanoquinodimethane, 7,7,8,8-tetracyanoquinodimethane, 4,4′,4″-tris(2-naphthylphenylamino)triphenylamine, 4,4′-Bis(N-carbazole)-1-1′-biphenyl, 1,3-bis(triphenylsilyl)benzene, 4,4′-bis(9-carbazolyl)-2,2′-dimethyl biphenyl, Bis(10-hydroxybenzo[h]quinolinato)beryllium, 1,3,5-tris(4-pyridin-3-ylphenyl)benzene, 8-hydroxyquinoline aluminum or Bis[2-(2-pyridinyl)phenolato]beryllium, and the like. The solvent can be, for example, a solvent such as chloroform, toluene, xylene or tetrahydrofuran which can dissolve the organic material but is insoluble in the matrix solution. The toluene has a density of 0.87 g/cm³, the xylene has a density of 0.88 g/cm³, and the tetrahydrofuran has a density of 0.89 g/cm³. Therefore, when the matrix solution is selected as water (water density is 1 g/cm³), the organic material solution can be spread on the surface of the matrix solution. Further, the density of chloroform is 1.5 g/cm³, although it is denser than water, chloroform can also float on the surface of water due to the surface tension of the liquid surface, so that an organic material solution using chloroform as a solvent can also be spread on the surface of the matrix solution.

In at least one example of the embodiment, the organic material solution can further comprise, for example, an additive that promotes formation of a more uniform and stable monomolecular layer of the organic material on the surface of the matrix solution, thereby improving the preparation efficiency of the organic film and improving the stability of the organic film. The additive can be, for example, a catalyst, and the catalyst can be, for example, octadecylamine, stearic acid, behenic acid or eicosanoid acid, and the like.

Step S102: forming an organic film.

In the present embodiment, for example, the organic material layer obtained in the step S101 is transferred onto a substrate to obtain an organic thin film in which molecules are arranged in order.

In this embodiment, the substrate can be, for example, a film layer on which an organic thin film is to be formed, and on which a cathode material layer, an anode material layer, or an organic functional layer has been formed. For example, the anode material layer can be a conductive film having a high work function, such as an ITO film or the like. The cathode material layer can be, for example, a conductive material having a low work function, such as a metal such as Al, Mg, or Ca. The organic functional layer can be, for example, an electron transport layer, an electron injection layer, an electron block layer, a hole transport layer, a hole injection layer, a hole blocking layer or a light-emitting layer, which has been prepared. In at least one example of the embodiment, after the organic material layer is transferred onto the substrate, for example, the organic material layer can be dried to sufficiently evaporate the solvent to obtain a dry and pure organic film.

In this embodiment, the substrate can be subjected to, for example, a cleaning treatment before transferring the organic material layer onto the substrate, so that the organic material can be more tightly bonded to the substrate. In this embodiment, for example, the substrate can be subjected to hydrophilic or hydrophobic treatment to make the surface of the substrate hydrophilic or hydrophobic. Thus, molecules of the organic material layer remain in order after being transferred to the substrate.

Step S141 and Step S102 will be described hereinafter in detail by taking polyvinyl carbazole (PVK) as the organic material, toluene as the solvent, octadecylamine (OA) as the catalyst, distilled water as the matrix solution, and indium tin oxide (ITO) as the substrate as an example.

Step S101: forming an organic material layer.

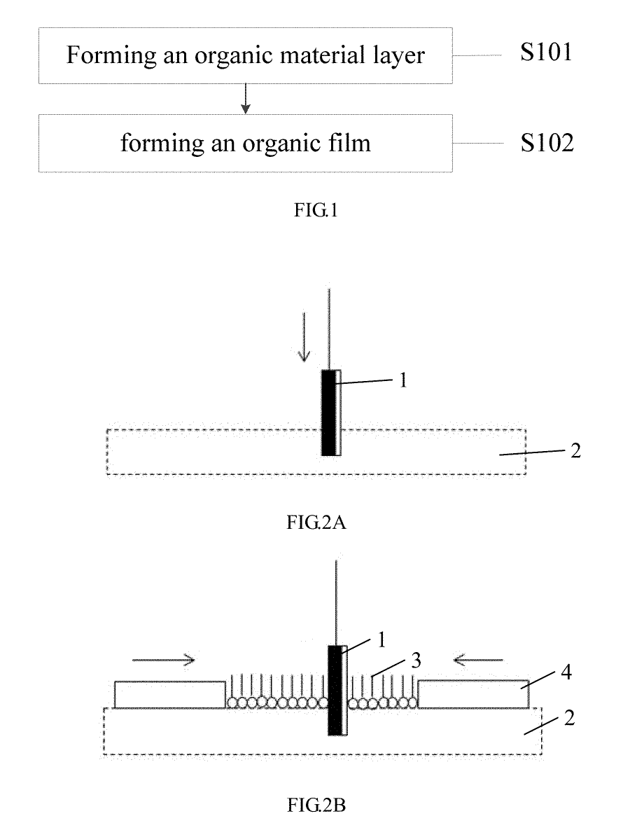

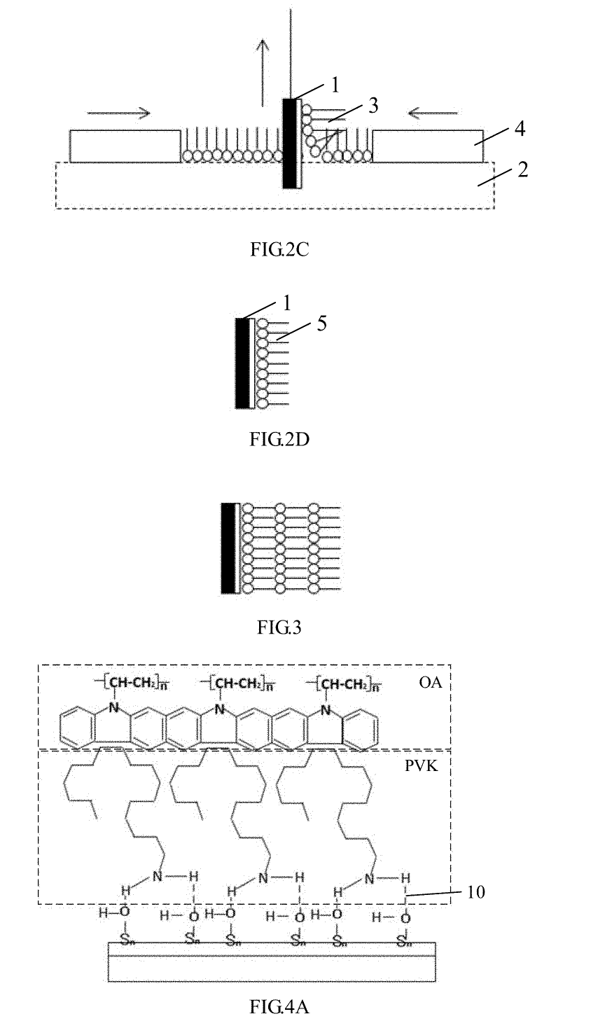

As illustrated in FIG. 2A, for example, a substrate 1, such as an ITO substrate adopted in the present example, can first be immersed in a matrix solution 2, such as distilled water adopted in the present example, and then a substrate pulling method can be employed after forming an organic material layer on the matrix solution 2. That is, the substrate 1 is pulled out of the matrix solution 2 at a rate to transfer the organic material layer onto the substrate 1.

As illustrated in FIG. 2B, after the substrate 1 is immersed in the matrix solution 2, for example, the formulated organic material solution 3 is spread on the surface of the matrix solution 2. In this example, the organic material solution can be formulated through the followings: for example, first an organic material such as polyvinyl carbazole (PVK) adopted in the present example and a catalyst such as octadecylamine (OA) employed in the present example are uniformly mixed with a molar ratio of 1:1 to 10:1, for example, a molar ratio of 3:1, 5:1 or 7:1, and then a mixture of PVK and OA is dissolved in a solvent (such as toluene selected in the present example) with a concentration of, for example, (0.5-5)×10⁻³ mol/L, such as, 1×10⁻³ mol/L or 2×10⁻³ mol/L, to form an organic material solution. In the organic material solution, PVK and OA can be combined, for example, in a ratio of 1:1 to form a PVK/OA molecular group having a hydrophilic group as an amino group and a hydrophobic group as a hydroxyl chain.

For example, during the process of spreading the organic material solution 3 on the matrix solution 2, the PVK/OA molecular group is arranged in order on the matrix solution 2 (the distilled water) with the hydrophilic group amino group (—NH₂) contacting with the base solution distilled water 2, and the hydrophobic group hydroxyl chain away from the base solution 2 (the distilled water). At this time, for example, a blocking tool such as a baffle 4 can be used to limit the spread area of the organic material solution 3 on the matrix solution 2, so that the PVK/OA molecule group forms a tight and ordered mono-molecule layer on the surface of the matrix solution 2.

For example, the ordered mono-molecule layer can be allowed to stand on the matrix solution 2 for 5-10 minutes (min) after its formation, for example 6 min, 8 min or 9 min, so that the solvent in the organic material solution 3 can be evaporated in some degree. Evaporation of the solvent causes the ordered mono-molecule layer to have a certain strength so that it can be transferred to the substrate 1 through a substrate pulling method in a subsequent preparation process.

Step S102, forming an organic film.

As illustrated in FIG. 2C, the organic material layer obtained in the step S101 can be transferred to the substrate by, for example, a substrate pulling method. In at least one example, the indium tin oxide (ITO) substrate 1 can be pulled out of the matrix solvent 2, for example, at a rate of 0.2-45 mm/min, for example 0.22 mm/min, 2 mm/min, 20 mm/min or 40 mm/min by using a film puller. During the pulling out of the ITO substrate 1, the indium atoms, tin atoms and oxygen atoms on the surface of the ITO substrate 1 attract the hydrophilic group amino group (—NH₂) of the PVK/OA molecular group formed in the step S101, and repel the hydrophobic group hydroxyl chain of the PVK/OA molecular group, so that, during pulling out the ITO substrate 1, the PVK/OA molecular group can be transferred to the surface of the ITO substrate in an orderly manner due to the attraction of the ITO substrate 1 on the hydrophilic group amino group (—NH₂) of the PVK/OA molecular group and the attraction of van der Waals force. That is, the organic material layer is transferred to the surface of the ITO substrate 1.

In at least one example, after the organic material layer is transferred onto the substrate 1, it can be vacuum dried by, for example, a drying device such as a vacuum drying oven to completely evaporate the solvent in the organic material layer, thereby forming an organic film 5 in which the molecules are ordered, as illustrated in FIG. 2D. In this example, the organic thin film 5 is a monomolecular layer in which molecules are arranged in order.

In at least one example, the ITO substrate can be subjected to a cleaning treatment, for example, before being immersed in the matrix solution. For example, the ITO substrate is washed sequentially with a cleaning agent, acetone, ethanol, and deionized water. For example, in the process of cleaning the ITO substrate with a cleaning agent, the cleaning agent can be, for example, a cleaning agent for optical glass, and the cleaning agent is mixed with distilled water in a ratio of, for example, 1:9 to form a mixed liquid, and the ITO substrate is immersed in the mixed liquid and is cleaned by use of ultrasonic wave for 30 minutes at a temperature of, for example, 45 V, to remove inorganic impurities such as dust on the surface of the ITO substrate. For example, after cleaning with a cleaning agent, the ITO substrate is rinsed with distilled water, and then the ITO substrate is immersed in acetone for ultrasonic cleaning to remove the cleaning agent remaining on the surface of the ITO substrate. Thereafter, the ITO substrate was immersed in ethanol for ultrasonic cleaning to remove acetone remaining on the surface of the ITO substrate. Finally, the ITO substrate was immersed in deionized water for ultrasonic cleaning to remove hydrogen ions, oxygen ions and the like on the surface of the ITO substrate. After finishing the cleaning, for example, the ITO substrate is placed in a vacuum drying oven and is dried at a temperature of 150° C. for 15 minutes, thereby obtaining a clean ITO substrate. In this embodiment, for example, an atomic force microscope can be used to test the surface roughness of the cleaned ITO substrate. The test results show that the surface roughness of the ITO substrate which has been cleaned is generally less than 10 nm, that is, the above cleaning method effectively improves the surface cleanliness of the ITO substrate.

In at least one example, after the ITO substrate cleaning is completed, for example, the surface of the ITO substrate can also be treated to make the surface hydrophilic. For example, the surface of the ITO substrate can be treated with an acid or alkali solution. For example, the surface of the ITO substrate is wiped with concentrated sulfuric acid to form a hydrophilic group (hydroxyl group, —OH) on the surface of the ITO substrate, thereby making the surface of the ITO substrate hydrophilic. The hydrophilic group amino group of the PVK/OA molecular group can be combined with the hydroxyl group on the surface of the ITO substrate so as to form a hydrogen bond, so that the ordered monomolecular layer of PVK/OA is bonded to the surface of the ITO substrate more stably.

In other examples of the present embodiment, for example, the surface of the substrate can be treated to be hydrophobic so that the hydrophobic group of the organic material can be bonded to the substrate, and the hydrophilic groups are arranged away from the surface of the substrate to form a mono-molecule layer with molecules arranged in order. At this time, for example, the organic material layer can be transferred to the substrate by the substrate immersing method, that is, in step S101, the substrate is immersed into the matrix solution after the organic material layer is formed, rather than immersing the substrate into the matrix solution in advance, thereby transferring the organic material layer onto the substrate.

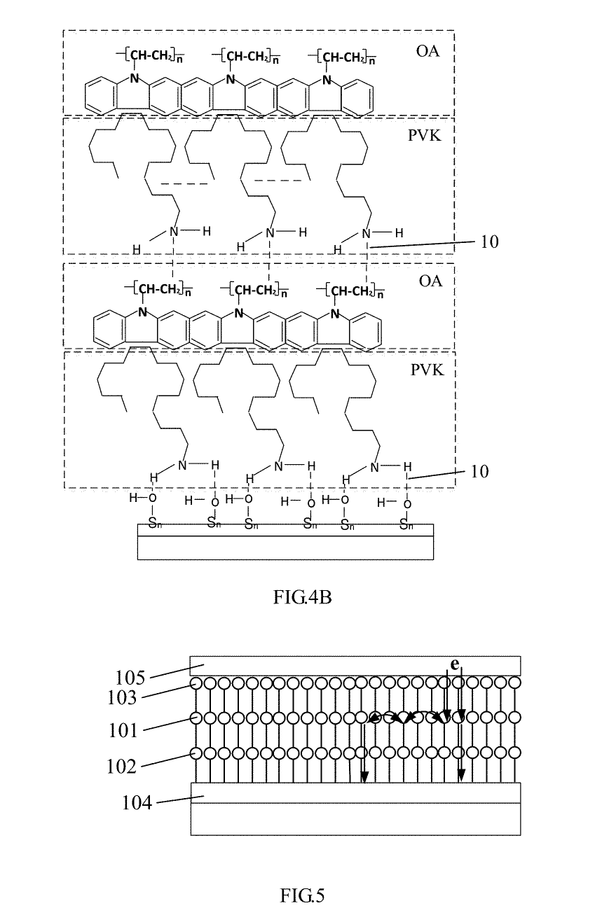

For example, FIG. 4A is a schematic diagram illustrating the molecular structure of the mono-molecule layer of PVK/OA of the present example in which PVK/OA molecules cluster are arranged in order when bonded to the surface of the ITO substrate. As illustrated in FIG. 4A, the hydrophilic group amino group on the PVK molecule of the PVK/OA cluster forms a hydrogen bond 10 with an oxygen atom on the surface of the ITO substrate, and is tightly bonded to the surface of the ITO substrate through the hydrogen bond 10. The hydrophobic group hydrocarbon chain located on the OA molecule is wound around the top of the PVK molecule at a certain mean square radius of gyration and thus arranged at a position away from the ITO substrate. In the PVK/OA molecular structure, the total length except the hydrocarbon chain portion is about 1.364 nm, while the length of the long carbon hydrocarbon chain is 285.3 nm to 382.9 nm. But the length of the PVK/OA molecular is greatly reduced as the molecular groups are tightly arranged and wound with a certain mean square radius of gyration under the side pressure of the slippery barrier. The height of the PVK/OA molecular cluster by ultimately agglomerating PVK and OA is determined by the height of the benzene ring of the PVK molecule, the vertical height of the OA molecule, and the agglomeration height of its hydrocarbon chain. In this embodiment, the height of the PVK/OA molecular cluster is about 25 nm.

In the present embodiment, step S101 and step S102 can be repeated, for example, for several times so as to form an organic film having a plurality of mono-molecular layers as illustrated in FIG. 3. The molecular structure of the organic film is as illustrated in FIG. 4B, and the multi-layered mono-molecular layers are attached to each other by hydrogen bonds 10, so that the formed multi-layered mono-molecule layers are tightly bonded. The organic film has high hole transport efficiency and can be used, for example, as a hole transport layer of an organic light emitting diode.

Molecules of the organic film prepared by the method of the present embodiment are arranged in order, so that photoelectrons can be transported by chemical bonds in the organic film, for example, by hydrogen bond. The bond energy of the hydrogen bond is second only to the bond energy of the ion bond and the covalent bond, and the bond energy is about 100-800 kJ/mol, and the bond energy is much larger than the bond energy of the van der Waals force. Therefore, in the organic film, both the electron transport efficiency and the hole transport efficiency are high, so that the matching ratio of electrons and holes is high, so that the electrical conductivity of the organic film can be improved, thereby improving the photoelectron transport efficiency. When the organic film is used as an organic functional layer of an organic light emitting diode, the luminous efficiency of the organic light emitting diode can be improved.

In this embodiment, each preparation process can be carried out, for example, in a vacuum environment, thereby ensuring that the finished organic film is not contaminated.

In this embodiment, for example, when the organic material is selected from 8-hydroxyquinoline aluminum or bis[2-(2-pyridyl)phenol] beryllium, and the catalyst is selected from stearic acid or behenic acid, the finished organic film has a high electron transport efficiency, and for example, can be used as an electron transport layer of an organic light emitting diode. Therefore, in the preparation process of the organic film, the substrate can be selected as a conductive material which has a low work function and can be used as a cathode of an organic light emitting diode, for example, a metal substrate of Al, Mg, Ca or the like.

In this embodiment, for example, when the organic material is selected from 4,4′-bis(9-carbazole)biphenyl, 1,3-bis(triphenylsilyl)benzene or 4,4′-bis(9-carbazolyl)-2,2′-dimethylbiphenyl, and the catalyst is selected as eicosanoid, the finished organic film can be used as, for example, a light emitting layer of an organic light emitting diode. Thus, in the preparation process of the organic film, the substrate can be, for example, an organic film which has been prepared for an electron transport layer or a hole transport layer, or a conductive material which can serve as a cathode or an anode.

In at least one embodiment, for example, when the organic material is selected from tetrafluorotetracyanoquinodimethane, 7,7,8,8-tetracyanoquinodimethane or 4,4′,4″-tri (2-naphthylphenylamino)triphenylamine, when the catalyst is selected from octadecylamine (OA), stearic acid (SA) or behenic acid (BA), the finished organic film can be used, for example, as a hole injection layer of an organic light emitting diode. Thus in the preparation process of the organic thin film, the substrate can be selected, for example, as a conductive material which has a high work function and can be used as an anode, such as a substrate of ITO.

In this embodiment, for example, when the organic material is bis(10-hydroxybenzo[h]quinoline)beryllium or 1,3,5-tris(4-pyridin-3-ylphenyl)benzene, the catalyst is stearic acid (SA) or behenic acid (BA), the finished organic film can be used for example, as an electron injection layer of an organic light emitting diode, and therefore, in the preparation process of the organic film, the substrate can be selected, for example, as a metal material which can be used as a cathode, such as a metal substrate of Al, Mg, Ca, or the like.

It should be noted that materials for the organic material and the catalyst in the present embodiment are not limited to the above examples, and one of ordinary skill in the art can select suitable materials according to actual requirements, which is not limited in this embodiment.

At least one embodiment of the present disclosure provides a method for manufacturing an organic light emitting diode, the method comprising: forming an anode, a cathode, and an organic functional layer between the anode and the cathode, wherein the organic functional layer is formed by using the method of preparing an organic film as described above.

In the present embodiment, the anode can employ, for example, a conductive film having a high work function, such as an ITO film or the like. The cathode can employ, for example, a conductive material having a low work function, such as a metal such as Al, Mg, Ca or the like.

In this embodiment, the organic functional layer can be, for example, one or more of an electron transport layer, an electron injection layer, an electron blocking layer, a hole transport layer, a hole injection layer, a hole blocking layer, and a light emitting layer, and is manufactured by the method for manufacturing an organic film as described, which will not be elaborated here.

Molecules of the organic film of the organic light emitting diode prepared by the method of the present embodiment are arranged in order, so that photoelectrons can be transported by chemical bonds in the organic film, for example, by hydrogen bond. The bond energy of the hydrogen bond is second only to the bond energy of the ion bond and the covalent bond, and the bond energy of the hydrogen bond is about 100-800 ki/mol, and the bond energy is much larger than the bond energy of the van der Waals force. Therefore, in the organic film, both the electron transport efficiency and the hole transport efficiency are high, so that the matching ratio of electrons and holes is high, thereby improving the electrical conductivity of the organic film, thereby improving the photoelectron transport efficiency, and finally improving the luminous efficiency of the organic light emitting diode.

At least one embodiment of the present disclosure provides an organic light emitting diode comprising a cathode, an anode, and an organic functional layer between the cathode and the anode, wherein the organic functional layer comprising at least one organic film in which molecules arc arranged in order, and the molecules of the at least one organic film comprises a hydrophilic group and a hydrophobic group.

For example, the organic film is a mono-molecular layer in which molecules are arranged in order. For example, the organic functional layer is one or more of an electron transport layer, an electron injection layer, an electron blocking layer, a hole transport layer, a hole injection layer, a hole blocking layer, and a light emitting layer.

For example, the organic light emitting diode as illustrated in FIG. 5 comprises a cathode 105, an anode 104, and organic functional layers 101/102/103. For example, the organic functional layers 101/102/103 are respectively a light emitting layer, a hole transport layer, and an electron transport layer. In this case, only the case where each functional layer comprises only one mono-molecule layer in which molecules are arranged in order is illustrated. In other examples of the embodiment, each functional layer can further comprise a plurality of mono-molecular layers. In this embodiment, as illustrated in FIG. 5, since the molecules of each functional layer are arranged in order, photoelectrons can be transmitted laterally or vertically in each functional layer, while in the organic functional layer in which molecules are arranged disorderly, photoelectrons can be transmitted in any direction and the transmission efficiency of the photoelectrons is low. Therefore, the organic functional layer of the organic light emitting diode in which the molecules are arranged in order according to the embodiment can make the transmission of photoelectrons have directionality, thereby greatly improving the transmission efficiency of the photoelectrons, improving the electrical conductivity of the organic functional layer, and further improving the electro-optic efficiency of the organic light emitting diode.

For example, in one example, the organic light emitting diode can further comprise an electron injection layer and a hole injection layer. For example, the electron injection layer is located between the cathode 105 and the electron transport layer 103, and the hole injection layer is located between the anode 104 and the hole transport layer 102. For example, the electron injection layer and the hole injection layer can be a mono-molecular layer in which molecules are arranged in order or a plurality of mono-molecular layers in which molecules are arranged in order.

In the present embodiment, the hole transport layer can employ, for example, an organic material such as polyvinylcarbazole (PVK) or poly 3,4-ethylenedioxythiophene-polystyrenesulfonic acid (PEDOT:PSS). The light emitting layer can employ, for example, an organic material, such as 4,4′-bis(9-carbazole)biphenyl, 1,3-bis(triphenylsilyl)benzene or 4,4′-bis(9-carbazolyl)-2,2′-dimethylbiphenyl. The hole injection layer can employ, for example, an organic material, such as tetrafluorotetracyanoquinodimethane, 7,7,8,8-tetracyanoquinodimethane or 4,4′,4″-Tris[2-naphthyl(phenyl)amino]triphenylamine. As the electron transport layer can employ, for example, an organic material such as 8-hydroxyquinoline aluminum or Bis[2-(2-pyridinyl)phenolato]beryllium. As the electron injection layer can employ, for example, an organic material such as Bis(10-hydroxybenzo[h]quinolinato)beryllium or 1,3,5-tris(4-pyridin-3-ylphenyl)benzene. Of course, one of ordinary skill in the art can also select other materials to prepare the organic functional layers according to actual requirements, which is not limited in this embodiment.

The organic light emitting diode according to the present embodiment comprises an organic functional layer in which molecules are arranged in order. In the organic functional layer, photoelectrons can be transported through chemical bonds, for example, by hydrogen bond. The bond energy of the hydrogen bond is second only to the bond energy of the ionic bond or the covalent bond, and its bond energy is about 100-800 kJ/mol. The bond energy is much larger than the bond energy of van der Waals force. Therefore, in the organic film, the matching ratio of electrons and holes is high, thereby improving the electrical conductivity of the organic film, thereby improving the photoelectron transmission efficiency, and finally improving the luminous efficiency of the organic light emitting diode.

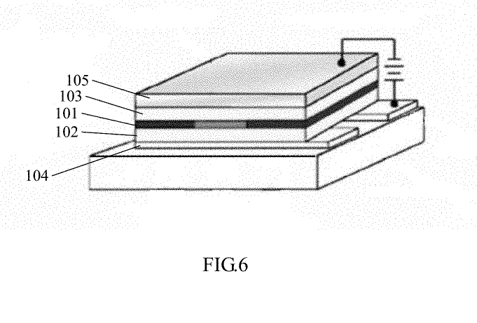

At least one embodiment of the present disclosure provides an organic light emitting display panel. As illustrated in FIG. 6, the display panel comprises any of the organic light emitting, diodes provided by the embodiments of the present disclosure, for example, comprising, a cathode 105, an anode 104, and an organic functional layer 101/102/103.

In this embodiment, the display panel can further comprise other functional layers and structural layers, such as a pixel driving circuit for driving the organic light emitting diode, a planarization insulating layer, and the like, which will not be elaborated in this embodiment.

At least one embodiment of the present disclosure also provides a display device comprising the display panel as described above. The display device can be any product or component having a display function, such as a liquid crystal panel, an electronic paper, an OLED panel, a mobile phone, a tablet computer, a television, a monitor, a laptop computer, a digital photo frame, a navigator, etc., which is not limited in the disclosure.

The organic light emitting display panel and the organic light emitting diode of the display device according to an embodiment of the present disclosure comprise an organic functional layer in which molecules are arranged in order. In the organic functional layer, photoelectrons can be transmitted by chemical bonds, for example, by hydrogen bond. The bond energy of the hydrogen bond is second only to the bond energy of the ionic bond or the bonding bond, and is about 100-800 kJ/mol. The bond energy is much larger than the bond energy of van der Waals force. Therefore, the matching ratio of electrons and holes in the organic film is high, so that the electrical conductivity of the organic film can be improved, thereby improving the photoelectron transmission efficiency, and the luminous efficiency of the organic light-emitting display panel and the display device is effectively improved.

The following points need to be explained:

(1) The drawings of the embodiments of the present disclosure relate only to the structures involved in the embodiments of the present disclosure, and other structures can be referred to normal demarks.

(2) For the sake of clarity, in the drawings depicting embodiments of the present disclosure, the thicknesses of layers or regions are enlarged or reduced, that is, these drawings are not drawn to actual scale. It will be understood that when an element such as a layer, film, region, or substrate is referred to as being “on” or “under” another element, it can be directly “on” or “below” of another element. Or there can be intermediate elements.

(3) In the case of no conflict, the embodiments of the present disclosure and the features in the embodiments can be combined with each other to obtain a new embodiment.

The foregoing are merely exemplary embodiments of the disclosure, but are not used to limit the protection scope of the disclosure. The protection scope of the disclosure shall be defined by the attached claims.

1. A method for manufacturing an organic film for an organic light emitting diode, comprising:
dispersing an organic material solution in a matrix solution to form an organic material layer;
transferring the organic material layer to a base substrate, so as to obtain an organic film in which molecules are arranged in order;
wherein the organic material solution comprises an organic material, and a molecular structure of the organic material comprises a hydrophilic group and a hydrophobic group.

2. The method for manufacturing the organic film for the organic light emitting diode according to claim 1, wherein the organic material layer is a mono-molecule layer in which molecules are arranged in order.

3. The method for manufacturing the organic film for the organic light emitting diode according to claim 1, wherein the organic material is an organic material for forming an electron transport layer, an electron injection layer, an electrode blocking layer, a hole transport layer, a hole injection layer, a hole blocking layer, or a light emitting layer.

4. The method for manufacturing the organic film for the organic light emitting diode according to claim 1, wherein the organic material is at least one of polyvinylcarbazole, poly 3,4-ethylenedioxythiophene-polystyrenesulfonic acid, perylenetetracarboxylic dianhydride, 8-hydroxyquinoline aluminum, tetrafluorotetracyanoquinodimethane, 7,7,8,8-tetracyanoquinodimethane, 4,4′,4″-tris(2-naphthylphenylamino)triphenylamine, 4,4′-Bis(N-carbazole)-1-1′-biphenyl, 1,3-bis(triphenylsilyl)benzene, 4,4′-bis(9-carbazolyl)-2,2′-dimethylbiphenyl, Bis(10-hydroxybenzo[h]quinolinato)beryllium, 1,3,5-tris(4-pyridin-3-ylphenyl)benzene, 8-hydroxyquinoline aluminum and Bis[2-(2-pyridinyl)phenolato]beryllium.

5. The method for manufacturing the organic film for the organic light emitting diode according to claim 1, wherein the organic material solution comprises a solvent, and the solvent is chloroform, toluene, xylene or tetrahydrofuran.

6. The method for manufacturing the organic film for the organic light emitting diode according to claim 1, wherein the organic material solution further comprises an additive that makes molecules of the organic material form a mono-molecule layer on a surface of the matrix solution.

7. The method for manufacturing the organic film for the organic light emitting diode according to claim 6, wherein the additive is at least one of octadecylamine, stearic acid, behenic acid or eicosanoid acid, and the additive is configured to be a catalyst.

8. The method for manufacturing the organic film for the organic light emitting diode according to claim 1, wherein the matrix solution is water or hydrophilic solution.

9. The method for manufacturing the organic film for the organic light emitting diode according to claim 1, comprising:
immersing the base substrate in the matrix solution;
dispersing the organic material solution on a surface of the matrix solution; and
then pulling the base substrate out of the matrix solution so as to transfer the organic material layer onto the base substrate.

10. The method for manufacturing the organic film for the organic light emitting diode according to claim 1, further comprising:
treating the base substrate so as to make the a surface of the base substrate hydrophilic or hydrophobic.

11. The method for manufacturing the organic film for the organic light emitting diode according to claim 1, further comprising:
drying the organic material layer after transferring the organic material layer onto the base substrate.

12. The method for manufacturing the organic film for the organic light emitting diode according to claim 1, wherein the base substrate is a cathode material layer, an anode material layer, or an organic functional layer.

13. The method for manufacturing the organic film for the organic light emitting diode according to claim 1, wherein each process of the method is carried out in a vacuum environment.

14. An organic light emitting diode, comprising a cathode, an anode, and an organic functional layer between the cathode and the anode, wherein
the organic functional layer comprises at least one organic film manufactured by the method according to claim 1, molecules of the organic film are arranged in order, and the molecules of the organic functional layer comprise a hydrophilic group and a hydrophobic group.

15. The organic light emitting diode according to claim 14, wherein the organic film is a mono-molecule layer in which molecules are arranged in order.

16. The organic light emitting diode according to claim 14, wherein the organic functional layer comprises at least one of an electron transport layer, an electron injection layer, an electron blocking layer, a hole transport layer, a hole injection layer, a hole blocking layer, and a light emitting layer.

17. The organic light emitting diode according to claim 14, wherein material for the organic functional layer comprises at least one of polyvinylcarbazole, poly 3,4-ethylenedioxythiophene-polystyrenesulfonic acid, perylenetetracarboxylic dianhydride, 8-hydroxyquinoline aluminum, tetrafluorotetracyanoquinodimethane, 7,7,8,8-tetracyanoquinodimethane, 4,4′,4″-tris(2-naphthylphenylamino)triphenylamine, 4,4′-Bis(N-carbazole)-1-1′-biphenyl, 1,3-bis(triphenylsilyl)benzene, 4,4′-bis(9-carbazolyl)-2,2′-dimethylbiphenyl, Bis(10-hydroxybenzo[h]quinolinato)beryllium, 1,3,5-tris(4-pyridin-3-ylphenyl)benzene, 8-hydroxyquinoline aluminum and Bis[2-(2-pyridinyl)phenolato]beryllium.

18. An organic light emitting display device, comprising the organic light emitting diode according to claim 14.

19. The method for manufacturing the organic film for the organic light emitting diode according to claim 2, wherein the organic material is at least one of polyvinylcarbazole, poly 3,4-ethylenedioxythiophene-polystyrenesulfonic acid, perylenetetracarboxylic dianhydride, 8-hydroxyquinoline aluminum, tetrafluorotetracyanoquinodimethane, 7,7,8,8-tetracyanoquinodimethane, 4,4′,4″-tris(2-naphthylphenylamino)triphenylamine, 4,4′-Bis(N-carbazole)-1-1′-biphenyl, 1,3-bis(triphenylsilyl)benzene, 4,4′-bis(9-carbazolyl)-2,2′-dimethylbiphenyl, Bis(10-hydroxybenzo[h]quinolinato)beryllium, 1,3,5-tris(4-pyridin-3-ylphenyl)benzene, 8-hydroxyquinoline aluminum and Bis[2-(2-pyridinyl)phenolato]beryllium.

20. The method for manufacturing the organic film for the organic light emitting diode according to claim 2, wherein the organic material solution comprises a solvent, and the solvent is chloroform, toluene, xylene or tetrahydrofuran.
